(19) United States
(12) Patent Application Publication
(10) Pub. No.: US 2016/0161648 A1
(43) Pub. Date: Jun. 9, 2016

(54) METHOD OF FABRICATING LARGE AREA BIREFRINGENT GRATING FILMS

(71) Applicant: TELEDYNE SCIENTIFIC & IMAGING, LLC, THOUSAND OAKS, CA (US)

(72) Inventors: DONG-FENG GU, THOUSAND OAKS, CA (US); MILIND MAHAJAN, THOUSAND OAKS, CA (US)

(73) Assignee: Teledyne Scienlific & Imaging. LLC

(21) Appl. No.: 14/559,769

(22) Filed: Dec. 3, 2014

(51) Int. Cl. G02B 5/18; G03H 1/04; G03F 7/00

(52) U.S. Cl. CPC G02B 5/1857; G02B 5/1833; G03F 7/0005; G03H 1/0465

(57) ABSTRACT

A method of fabricating large area birefringent grating films requires directing a UV beam through a large-scale LC polymer film alignment template on which a predetermined periodic alignment pattern has been imprinted and onto a photo-alignment layer such that the pattern is transferred thereon. The alignment template is fabricated by directing a collimated linearly polarized UV beam through a birefringent prism to produce two UV beams, which are directed onto a photo-alignment layer through a uniform quarter-wave plate to create a UV hologram which imprints the desired pattern onto the photo-alignment layer. These steps are repeated on different portions of the photo-alignment layer to create a large-scale photo-alignment layer. The photo-alignment layer, with a desired alignment pattern transferred with UV exposure through an alignment template, is then coated with a polymerizable LC material such that the desired pattern is followed by the liquid crystal molecules in the coating, which is then exposed with a UV beam so as to photo-polymerize the polymerizable LC material, and the coating is continued till the total coating thickness reaches either quarter-wave or half-wave retardation values at the wavelength of the UV source passing through the alignment template. Alternatively, a new alignment template can also be fabricated using a pre-existing alignment template with a half-wave retardation at the exposing UV wavelengths, and the alignment periodicity of the new alignment template is about half as the periodicity in the pre-existing alignment template.

### BACKGROUND OF THE INVENTION

1. Field of the Invention

This invention relates generally to methods of fabricating birefringent grating films, and more particularly to methods of fabricating large area birefringent grating films.

2. Description of the Related Art

Birefringent materials, characterized as having a refractive index that depends on the polarization and propagation direction of light impinging on the material, find application in many devices. One type of device which exhibits the optical property of birefringence is the birefringent grating film. In a birefringent grating film, the in-plane extraordinary optical axis changes along the grating axis periodically in a sinusoidal way. If the grating film retardation is half wavelength with respect to a circularly polarized incoming beam, the grating film acts as a perfect phase ramp prism with nearly 100% diffraction efficiency. Other advantages of such birefringent gratings include extremely small volume, high polarization selectivity or contrast ratio, and wide bandwidth or wide angle performance. These features enable birefringent gratings to be used in applications such as polarization beam splitters, agile beam steering, light shutters, filters, and displays.

The fabrication of high diffraction-efficiency birefringent grating films conventionally starts with UV-exposing a photo-alignment layer that creates a polarized UV hologram with traditional heterodyne interference of two circularly polarized UV beams. The UV exposure imprints a periodic alignment pattern to the photo-alignment layer upon which a layer of birefringent material, usually a photo-polymerizable liquid crystal, is then coated as the grating layer. In the grating layer, the liquid crystal molecules follow the periodic alignment pattern. Due to short wavelength, long exposure time, and large beam size, it is extremely difficult to achieve a high quality periodic alignment pattern.

An alternative way to imprint a periodic alignment pattern is to direct a collimated UV laser through a birefringent prism and a quarter wave plate, with the resulting two circularly polarized beams exposing a photo-alignment layer. Birefringent prisms are typically made from birefringent crystals. However, it is nearly impossible to procure birefringent prisms with sufficient birefringence and with an aperture of greater than 3″, due to the difficulty in finding large natural crystals of high birefringence. Those prisms which are available often have poor transmissivity; for example, a 3″ Calcite Wallaston prism only transmits about 30% of the UV light impinging on it, thereby requiring a few hours or more of exposure time, depending on the power of the UV laser. The limitations mentioned in the above two methods act as a bottleneck for volume production of birefringent grating films.

### SUMMARY OF THE INVENTION

A method of fabricating birefringent grating films is presented, which enables large area birefringent grating films to be made quickly and inexpensively.

The present birefringent grating film fabrication method requires that an alignment template of a liquid crystal (LC) polymer film alignment template be created, in which a desired periodic alignment pattern has been imprinted. With the alignment template formed, an ultraviolet (UV) beam is directed through the alignment template and onto a photo-alignment layer on a substrate, such that the periodic alignment pattern is transferred from the alignment template to the photo-alignment layer. Here the periodic alignment pattern refers to the pattern of a preferred alignment direction for the nematic director of a LC material once it is in contact with the alignment surface.

Once the desired periodic alignment pattern has been transferred to the photo-alignment layer, the following steps are preferably performed to produce a birefringent grating film. A solution that contains a polymerizable LC material and a solvent is spin-coated onto the photo-alignment layer. The solvent is air-dried or baked off such that the polymerizable LC material goes into a nematic liquid crystal phase and its liquid crystal molecular orientation follows the alignment pattern created on the photo-alignment layer. This is followed by UV-exposing the polymerizable LC material coating in a nitrogen blanket so as to photo-polymerize the polymerizable LC material coating. The spin-coating, air-drying or baking and UV-exposing steps are repeated until the thickness of the polymerizable LC material coating is such that it provides half-wave retardation at the wavelength at which the grating is to be used, thereby providing a birefringent grating film.

The LC polymer film alignment template is preferably fabricated as follows. A collimated linearly polarized UV beam is directed through a birefringent prism, with the linear polarization at 45 degrees with respect to the optical axes of the birefringent prism, to produce two UV beams having the same intensity amplitudes, orthogonal linear polarizations, and with a predetermined angle between the two UV beams. The two UV beams are directed onto a second photo-alignment layer on a substrate through a uniform quarter-wave plate, becoming two circularly polarized UV beams with opposite handedness. The interference of these two circularly polarized UV beams creates a linear polarization pattern when it impinges onto the surface of the second photo-alignment layer, with the polarization direction changing periodically along an axis that is the dissect line of the UV beam incident plane and the alignment surface. The periodicity or “pitch P” of the linear polarization change depends on the angle θ between the two UV beams: P=λ/sin θ, where λ, is the UV beam wavelength. With sufficient exposure time, this UV hologram will transfer a desired periodic alignment pattern on the photo-alignment layer, and the alignment direction is sinusoidal: if the grating axis is along x-axis, then the x component of the direction vector is cos(2πx/P). The photo-alignment layer is then coated with a polymerizable LC material such that LC molecules in the polymerizable LC material follow the periodic alignment pattern once the coating gets into a nematic phase (a LC phase) during drying of the solvent. The coating of polymerizable LC material is then exposed with a UV beam so as to photo-polymerize the polymerizable LC material.

These and other features, aspects, and advantages of the present invention will become better understood with reference to the following drawings, description, and claims.

### BRIEF DESCRIPTION OF THE DRAWINGS

FIG. 1 is a diagram illustrating one method of fabricating a photo-alignment layer from which birefringent grating films can be produced in accordance with the present invention.

FIG. 2 is a diagram illustrating an alternative method of fabricating a photo-alignment layer from which birefringent grating films can be produced in accordance with the present invention.

FIGS. 3 and 4 are diagrams illustrating a method of fabricating a LC polymer film alignment template suitable for use fabricating a photo-alignment layer as shown in FIG. 1.

FIG. 5 is a diagram illustrating a method of fabricating a LC polymer film alignment template suitable for use fabricating a photo-alignment layer as shown in FIG. 2.

FIG. 6 is a flow diagram illustrating one possible set of steps for fabricating a birefringent film using a photo-alignment layer as shown in FIG. 1 or 2.

### DETAILED DESCRIPTION OF THE INVENTION

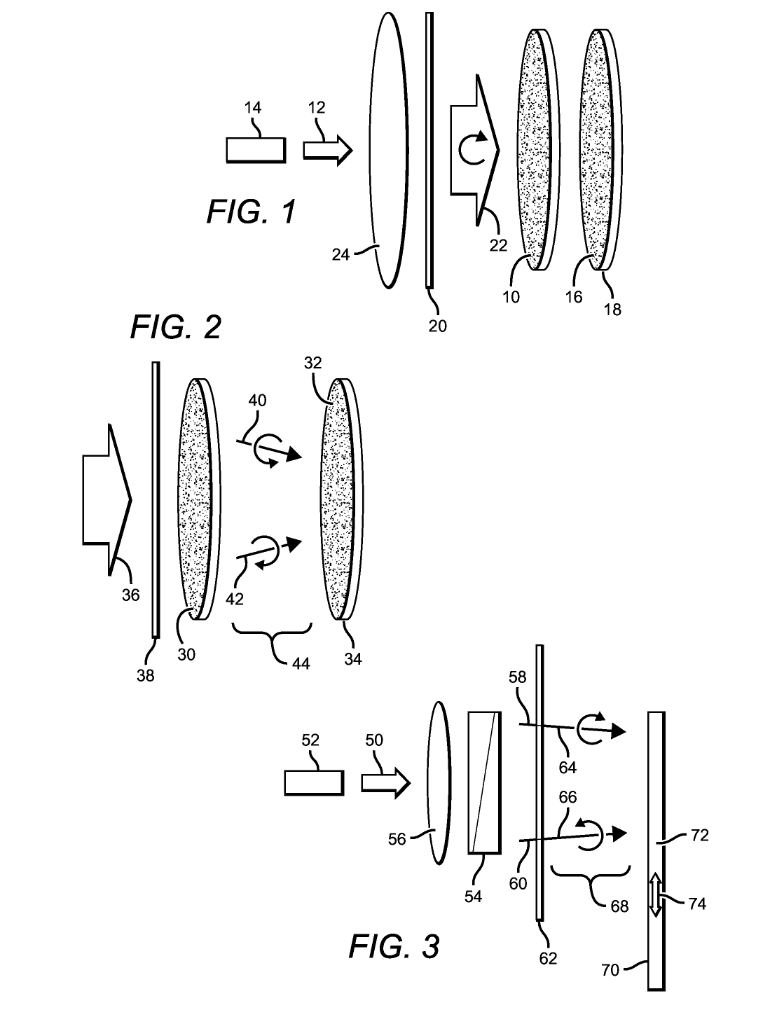

In accordance with the present invention, large area birefringent grating films are produced using a properly exposed photo-alignment layer. One way in which such a photo-alignment layer might be produced is illustrated in FIG. 1.

First, a LC polymer film alignment template 10 must be created, on which the LC molecules follow a periodic alignment pattern. Techniques for creating alignment template 10 are discussed below. Once the alignment template is prepared, an ultraviolet (UV) beam 12, preferably provided by a UV laser 14, is directed through alignment template 10 onto a photo-alignment layer 16 formed on a substrate 18, such that the periodic alignment pattern is transferred from the alignment template onto the photo-alignment layer. The photo-alignment layer can then be used for coating and polymerizing a LC monomer layer to fabricate a large area birefringent grating film (as discussed in more detail below). Substrate 18 is typically glass, and photo-alignment layer 16 can be formed on either the top or bottom side of the substrate.

In one preferred version of the present method, UV beam 12 has an associated center wavelength, and alignment template 10 has a quarter-wave retardation at the UV beam's center wavelength. The UV beam is preferably either a linearly polarized, collimated UV laser beam, or a collimated UV beam from a broadband source which has passed through a narrowband bandpass filter and a linear polarizer (not shown). A uniform quarter-wave plate 20 is interposed between UV beam 12 and alignment template 10 so as to create a circularly polarized UV beam 22 which passes through the alignment template and transfers the periodic alignment pattern in the alignment template onto photo-alignment layer 16. In this method alignment template 10 should have a quarter-wave retardation as described here, the periodicity or the pitch of the alignment pattern transferred onto the photo-alignment layer will be the same as that in the alignment template.

An alternative method of creating a properly exposed photo-alignment layer is illustrated in FIG. 2. Here, an LC polymer film alignment template 30 is provided with a predetermined periodic alignment pattern exists in the local optical axis of the LC molecules and with a half-wave retardation at a UV beam wavelaength, along with a photo-alignment layer 32 formed on a substrate 34. A UV beam 36 is directed through alignment template 30 onto photo-alignment layer 32 such that a desired periodic alignment pattern is transferred from the alignment template onto the photo-alignment layer after sufficient exposure time; the exposed photo-alignment layer can then be used for coating and polymerizing a LC monomer layer to fabricate a large area birefringent grating film.

The UV beam 36 has an associated center wavelength, and alignment template 30 has a half-wave retardation at the UV beam's center wavelength. UV beam 36 is either a linearly polarized, collimated UV laser beam, or a polarized, collimated UV beam from a broadband source which has passed through a narrowband bandpass filter 38 interposed between the UV beam and alignment template 30. Due to the half-wave retardation at the UV beam's center wavelength, the incoming UV beam causes alignment template 30 to function as a polarization beam splitter which generates left- and right-hand circular polarized beams 40, 42; beams 40 and 42 have the same intensity, but are separated by an angle 2a (again here a is the diffraction angle of a circularly polarized UV beam passing the alignment template and defined by sin α=λ/P, where P is the periodicity of the alignment pattern in the alignment template and λ is the UV wavelength), thereby creating a UV hologram 44 which transfers a periodic alignment pattern on photo-alignment layer 32. The periodic alignment pattern in alignment template 30 will be transferred, in a certain proportion, onto photo-alignment layer 32, which can be used for coating and polymerizing a LC monomer layer to fabricate large area birefringent grating films. Here the new pitch P′ is defined as P′=λ/sin 2 θ=P/2 cos θ. Therefore, when the angle θ is small, the new pitch in the alignment layer is about half of that in the alignment template. Further reduction of the grating pitch can be realized by building grating layers with half UV wavelength retardation on the alignment layer and using it as the new alignment template for the next alignment layer transfer. This technique enables the use of birefringent prisms with low birefringence, such as quartz, to fabricate alignment templates with very small pitches. On the other hand, a sequence of alignment templates with pitches reduced at nearly ½ⁿ ratio on each fabrication step can be fabricated. These alignment templates would be useful in fabrication of a multi-stage beam steering device with the steering angle of each stage in binary cascading fashion.

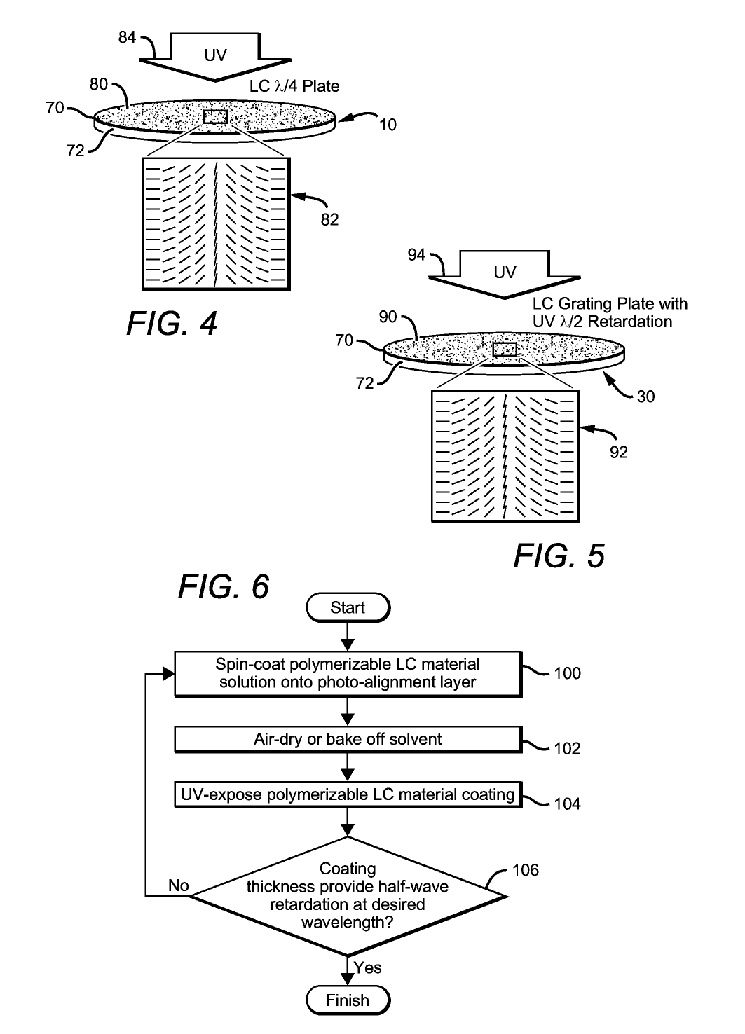

A preferred method of creating a LC polymer film alignment template 10 as shown in FIG. 1, with a quarter-wave retardation at the center wavelength of UV beam 12, is shown in FIGS. 3 and 4. A collimated linearly polarized UV beam 50 from a source 52 is directed through a birefringent prism 54, typically via a beam expansion lens or lenses 56, with the linear polarization at 45 degrees with respect to the optical axes of the birefringent prism. The prism produces two UV beams 58, 60, which have the same intensity amplitudes but orthogonal polarizations, with a predetermined angle between the two UV beams. UV beams 58 and 60 are directed through a uniform quarter-wave plate 62, which generates left- and right-hand circular polarized beams 64, 66. Beams 64 and 66 interfere, thereby creating a UV hologram 68 which transfers the desired periodic alignment pattern onto a photo-alignment layer 70 (which resides on a substrate 72).

To make large area birefringent grating films, the size of photo-alignment layer 70 should exceed that required for the desired periodic alignment pattern. Then, after the desired periodic alignment pattern is transferred onto a portion of photo-alignment layer 70, the photo-alignment layer can be re-positioned, using an X-Y stepper 74 for example, such that a new portion of layer 70 can be exposed. The process described above is then repeated such that the desired periodic alignment pattern is transferred onto the new portion of photo-alignment layer 70. These transferring and re-positioning steps can be repeated as needed to fill photo-alignment layer 70 with multiple instances of the desired periodic alignment pattern, thereby providing a large-scale photo-alignment layer. As discussed in more detail below, this large-scale photo-alignment layer can then be used to create a large-scale LC polymer film alignment template, which can then in turn be used to create large area birefringent grating films.

Once the desired periodic alignment pattern has been transferred onto photo-alignment layer 70, the fabrication of alignment template 10 continues as shown in FIG. 4. Photo-alignment layer 70 is coated with a polymerizable LC material 80 such that the desired periodic alignment pattern 82 is transferred from the photo-alignment layer to the coating, in which the liquid crystal molecules follow the sinusoidal alignment direction in the photo-alignment layer. Polymerizable LC material coating 80 is then exposed with a UV beam 84, usually from a broadband UV source, so as to photo-polymerize the polymerizable LC material, thereby creating a alignment template 10 that is a λ/4 plate with a periodic LC alignment pattern. Polymerizable LC material 80 is preferably a reactive mesogen material.

The step of coating photo-alignment layer 70 preferably comprises spin-coating a solution that contains a polymerizable LC material and a solvent onto layer 70. The solvent is then air-dried or baked off such that the resulting polymerizable LC material layer goes into a nematic liquid crystal phase and its LC molecular orientation follows the alignment pattern created on the photo-alignment layer. The step of exposing the coating of polymerizable LC material with a UV beam preferably comprises UV-exposing the polymerizable LC material layer in a nitrogen blanket so as to photo-polymerize the polymerizable LC material coating. The spin speed and concentration of the polymerizable LC material should be such that, after the solvent is evaporated, the thickness of the coating provides quarter-wave retardation at the center wavelength of UV beam 12.

A preferred method of creating a LC polymer film alignment template 30 as shown in FIG. 2, with a half-wave retardation at the center wavelength of UV beam 36, is shown in FIGS. 3 and 5. As for the alignment template with a quarter-wave retardation discussed above, the process begins as shown in FIG. 3, by creating a photo-alignment layer 70 onto which the desired periodic alignment pattern has been transferred.

Once the desired periodic alignment pattern has been transferred onto photo-alignment layer 70, the fabrication of alignment template 30 continues as shown in FIG. 5. Photo-alignment layer 70 is coated with a polymerizable LC material 90 such that the desired periodic alignment pattern 92 is transferred from the photo-alignment layer to the coating. Polymerizable LC material coating 90 is then exposed with a UV beam 94, usually from a broadband source, so as to photo-polymerize the polymerizable LC material, thereby creating a alignment template 30 that is a λ/2 plate with a periodic LC alignment pattern.

As above, the step of coating photo-alignment layer 70 preferably comprises spin-coating a solution that contains a polymerizable LC material and a solvent onto layer 70. The solvent is then air-dried or baked off such that the resulting polymerizable LC material layer goes into a nematic liquid crystal phase and its LC molecular orientation follows the alignment pattern created on the photo-alignment layer. The step of exposing the coating of polymerizable LC material with a UV beam preferably comprises UV-exposing the polymerizable LC material layer in a nitrogen blanket so as to photo-polymerize the polymerizable LC material coating. The spin speed and concentration of the polymerizable LC material should be such that, after the solvent is evaporated, the thickness of the coating provides half-wave retardation at the center wavelength of UV beam 36.

Once the desired periodic alignment pattern has been transferred onto the photo-alignment layer (16, 32) as described above, large area birefringent grating films can be fabricated in the following manner, which is illustrated in FIG. 6. Note that there are numerous ways in which an photo-alignment layer can be used to produce birefringent grating films; the method described below is but one possibility.

First, a solution that contains a polymerizable LC material and a solvent is spin-coated onto the photo-alignment layer (step 100). The solvent is then air-dried or baked off such that the polymerizable LC material goes into a nematic liquid crystal phase and its liquid crystal molecular orientation follows the alignment pattern created on the photo-alignment layer (step 102). Then, the polymerizable LC material coating is UV-exposed in a nitrogen blanket so as to photo-polymerize the polymerizable LC material coating (step 104). The steps of spin-coating, air-drying or baking and UV-exposing are repeated until the thickness of the polymerizable LC material coating is such that it provides half-wave retardation at the wavelength at which said grating is to be used (step 106), thereby providing a birefringent grating film.

The method described herein eliminates the need for a large crystal with high birefringence to achieve a high yield and throughput, increases the UV intensity/transmission thus enabling a shorter UV exposure time, and realizes a straightforward fabrication operation.

The embodiments of the invention described herein are exemplary and numerous modifications, variations and rearrangements can be readily envisioned to achieve substantially equivalent results, all of which are intended to be embraced within the spirit and scope of the invention as defined in the appended claims.

We claim:

1. A method of fabricating a birefringent grating film, comprising:
creating a liquid crystal (LC) polymer film alignment template on which a desired periodic alignment pattern has been imprinted;
providing an ultraviolet (UV) beam;
providing a photo-alignment layer on a substrate; and
directing said UV beam through said alignment template such that a periodic alignment pattern based on the pattern imprinted on said alignment template is transferred onto said photo-alignment layer.

2. The method of claim 1, said UV beam having an associated center wavelength, wherein said alignment template has a quarter-wave retardation at said UV beam's center wavelength and said UV beam is either a polarized, collimated UV laser beam, or a collimated UV beam which has passed through a narrowband bandpass filter and a linear polarizer, further comprising a uniform quarter-wave plate interposed between said UV beam and said alignment template so as to create a circularly polarized UV beam which passes through said alignment template, such that the periodic alignment pattern provided in the alignment template is transferred onto said photo-alignment layer.

3. The method of claim 1, said UV beam having an associated center wavelength, wherein said alignment template has a half-wave retardation at said UV beam's center wavelength and said UV beam is either a linearly polarized, collimated UV laser beam, or a linearly polarized, collimated UV beam which has passed through a narrowband bandpass filter interposed between said UV beam and said alignment template, such that said filtered UV beam passes through said alignment template that acts as a circular polarization beam splitter and creates a UV hologram which transfers a periodic alignment pattern onto said photo-alignment layer.

4. The method of claim 1, further comprising:
spin-coating a solution that contains a polymerizable LC material and a solvent onto the photo-alignment layer;
air-drying or baking said solvent off such that the polymerizable LC material goes into a nematic liquid crystal phase and its liquid crystal molecular orientation follows the periodic alignment pattern created on the photo-alignment layer;
UV-exposing said polymerizable LC material coating in a nitrogen blanket so as to photo-polymerize the polymerizable LC material coating; and
repeating said spin-coating, air-drying or baking and UV-exposing steps until the thickness of said polymerizable LC material coating is such that it provides half-wave retardation at the wavelength at which said grating is to be used, thereby providing a birefringent grating film.

5. The method of claim 1, wherein said step of creating a liquid crystal (LC) polymer film alignment template comprises:
providing a collimated linearly polarized ultraviolet (UV) beam;
directing said linearly polarized ultraviolet (UV) beam through a birefringent prism, with the linear polarization at 45 degrees with respect to the optical axes of the birefringent prism, to produce two UV beams having the same intensity amplitudes, orthogonal linear polarizations, and with a predetermined angle between said two UV beams;
providing a second photo-alignment layer on a substrate;
directing said two UV beams having orthogonal linear polarizations through a uniform quarter-wave plate so as to create a UV hologram which imprints said desired periodic alignment pattern onto said second photo-alignment layer;
coating said second photo-alignment layer with a polymerizable liquid crystal (LC) material such that said desired periodic alignment pattern is transferred from said second photo-alignment layer to said coating of polymerizable LC material; and
exposing said coating of polymerizable LC material with a UV beam so as to photo-polymerize the polymerizable LC material.

6. The method of claim 5, wherein said step of coating said second photo-alignment layer comprises:
spin-coating a solution that contains a polymerizable LC material and a solvent onto the second photo-alignment layer;
air-drying or baking said solvent off such that the resulting polymerizable LC material layer goes into a nematic liquid crystal phase and its liquid crystal molecular orientation follows the alignment pattern created on the second photo-alignment layer, said step of exposing said coating of polymerizable LC material with a UV beam comprising UV-exposing said polymerizable LC material layer in a nitrogen blanket so as to photo-polymerize the polymerizable LC material coating; and
controlling the spin speed the concentration of said polymerizable LC material such that, after said solvent is evaporated, the thickness of said coating provides quarter-wave retardation at the center wavelength of said UV beam used to transfer said periodic alignment pattern onto said photo-alignment layer.

7. The method of claim 5, wherein said step of coating said second photo-alignment layer comprises:
spin-coating a solution that contains a polymerizable LC material and a solvent onto the second photo-alignment layer;
air-drying or baking said solvent off such that the resulting polymerizable LC material layer goes into a nematic liquid crystal phase and its liquid crystal molecular orientation follows the alignment pattern created on the second photo-alignment layer, said step of exposing said coating of polymerizable LC material with a UV beam comprising UV-exposing said polymerizable LC material layer in a nitrogen blanket so as to photo-polymerize the polymerizable LC material coating; and
controlling the spin speed and the concentration of said polymerizable LC material such that, after said solvent is evaporated, the thickness of said coating provides half-wave retardation at the center wavelength of said UV beam used to transfer said desired periodic alignment pattern on said photo-alignment layer.

8. The method of claim 5, wherein said second photo-alignment layer has a size exceeding that of said desired periodic alignment pattern,
further comprising:
after transferring said desired periodic alignment pattern onto said second photo-alignment layer and before performing said coating and UV exposing steps, using an X-Y stepper to move said second photo-alignment layer;
repeating said transferring of said desired periodic alignment pattern on a new portion of said second photo-alignment layer; and
repeating said transferring and moving steps as needed to fill said second photo-alignment layer with multiple instances of said desired periodic alignment pattern;
thereby providing a large-scale LC polymer film alignment template after said polymerizable LC material coating and UV exposing steps of are performed.

9. The method of claim 5, wherein said polymerizable LC material is a reactive mesogen material.

10. The method of claim 8, further comprising:
spin-coating a solution that contains a polymerizable LC material and a solvent onto the photo-alignment layer on which said desired periodic alignment pattern has been transferred using said large-scale LC polymer film alignment template;
air-drying or baking said solvent off such that the polymerizable LC material goes into a nematic liquid crystal phase and its liquid crystal molecular orientation follows the alignment pattern created on the photo-alignment layer; UV-exposing said polymerizable LC material coating in a nitrogen blanket so as to photo-polymerize the polymerizable LC material coating; and
repeating said spin-coating, air-drying or baking and UV-exposing steps until the thickness of said polymerizable LC material coating is such that it provides half-wave retardation at the wavelength at which said grating is to be used, thereby providing a birefringent grating film.

11. The method of claim 3, wherein said alignment template with half-wave retardation at said UV beam's center wavelength is a first alignment template, further comprising producing a second alignment template having a pitch that is about half that found in said first alignment template, said step of producing a second alignment template comprising:
coating a photo-alignment layer on which said desired periodic alignment pattern has been transferred using said first alignment template with a polymerizable LC material to reach half-wave retardation value; and
polymerizing said polymerizable LC material.

12. The method of claim 11, further comprising:
producing a third alignment template having a pitch that is about half that found in said second alignment template, said step of producing a third alignment template comprising:
coating a photo-alignment layer on which said desired periodic alignment pattern has been transferred using said second alignment template with a polymerizable LC material to reach half-wave retardation value; and
polymerizing said polymerizable LC material; and
repeating said coating and polymerizing steps as needed to produce a sequence of alignment templates with further alignment periodicity reductions in a fashion of (½ⁿ (n is the nth exposing, coating, and UV-polymerization processing step).
